(19) United States
(12) Patent Application Publication
(10) Pub. No.: US 2026/0040924 A1
(43) Pub. Date: Feb. 5, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Seran OH, Suwon-si (KR); Myungho KONG, Suwon-si (KR); Sukhoon KIM, Suwon-si (KR); Yeonuk KIM, Suwon-si (KR); Joenggi YUN, Suwon-si (KR); Dosun LEE, Suwon-si (KR)

(73) Assignee: Samsung Electronics Co., Ltd., Suwon-si (KR)

(21) Appl. No.: 19/029,325

(22) Filed: Jan. 17, 2025

(30) Foreign Application Priority Data
Jul. 31, 2024 (KR) 10-2024-0101645

(51) Int. Cl. H01L 23/532; H01L 21/3213; H01L 21/768; H01L 23/522; H01L 23/528

(52) U.S. Cl. CPC H01L 23/53252; H01L 21/76844; H01L 23/5226; H01L 23/5283; H01L 21/32139; H01L 21/76804; H01L 21/76879; H01L 23/53228

(57) ABSTRACT

A semiconductor device includes a first structure including a first insulating layer and a first conductive wiring arranged on the first insulating layer, a second-1 insulating layer arranged above the first structure in a first direction, a via hole penetrating the second-1 insulating layer in the first direction, a barrier layer arranged at a lower side of the via hole, and a via plug electrically connected to the first conductive wiring and arranged to fill a remaining space in an internal space of the via hole, excluding the barrier layer.

### CROSS-REFERENCE TO RELATED APPLICATION

This application is based on and claims priority under 35 U.S.C. § 119 to Korean Patent Application No. 10-2024-0101645, filed on Jul. 31, 2024, in the Korean Intellectual Property Office, the disclosure of which is incorporated by reference herein in its entirety.

### BACKGROUND

The inventive concept relates to a semiconductor device and a method of manufacturing the same.

As electronic devices become lighter and deliver higher performance, there is an increasing demand for miniaturization and higher performance in the semiconductor device field. In line with this trend, the critical dimension (CD) of a wiring of a semiconductor device is also decreasing, and as the width of the wiring decreases, research and development are continuously being conducted to reduce increases in resistance. The above-mentioned background technology is possessed or obtained in the process of deriving the inventive concept and cannot necessarily be said to be known technology disclosed to the general public before the application of the inventive concept.

### SUMMARY

According to an aspect of the inventive concept, there is provided a semiconductor device including a first structure including a first insulating layer and a first conductive wiring arranged on the first insulating layer, a second-1 insulating layer arranged above the first structure in a first direction, a via hole penetrating the second-1 insulating layer in the first direction, a barrier layer arranged at a lower side of the via hole, and a via plug electrically connected to the first conductive wiring and arranged to fill a remaining space in an internal space of the via hole, excluding the barrier layer.

According to an embodiment, at least a portion of a side surface of the via plug may be in direct contact with the second-1 insulating layer.

According to an embodiment, the barrier layer may include a bottom layer covering a lower portion of the via plug. For example, a height of the barrier layer may be less than or equal to half a height of the via hole.

According to an embodiment, the barrier layer may extend upward from an edge of the bottom layer along an inner wall of the via hole. For example, the barrier layer may further include a side wall arranged between a lower side surface of the via plug and the second-1 insulating layer.

According to an embodiment, the via plug may have a shape stepped inward from an outer surface of the via plug. For example, the side wall of the barrier layer may be accommodated in the stepped shape of the via plug.

According to an embodiment, the via plug may include a first portion having an outer surface surrounded by the side wall of the barrier layer, and a second portion having an outer surface that is not surrounded by the side wall of the barrier layer. For example, the outer surface of the second portion may extend along the inner wall of the via hole and form a continuous surface with an outer surface of the side wall of the barrier layer.

According to an embodiment, the first conductive wiring and the via plug may include different metals from each other.

According to an embodiment, a resistivity scaling factor of a material included in the first conductive wiring may be greater than 6.5×10⁻¹⁶ Ωm², whereas a resistivity scaling factor of a material included in the via plug may be less than 6.5×10⁻¹⁶ Ωm².

According to an embodiment, the first conductive wiring may include copper (Cu), and the via plug may include ruthenium (Ru).

According to an embodiment, the semiconductor device may further include a second-2 insulating layer arranged above the second-1 insulating layer and the via plug, and a conductive pattern electrically connected to the via plug and arranged on the second-2 insulating layer. For example, the conductive pattern may include a metal that is different from that of the first conductive wiring.

According to an embodiment, a critical dimension (CD) of the conductive pattern may be smaller than a CD of the first conductive wiring.

According to an embodiment, a CD of the via hole may be 20 nm or less, and an aspect ratio (AR) of the via hole may be 2 or less.

According to an embodiment, a diameter of the barrier layer may be greater than a diameter of a portion of the first conductive wiring, which is exposed through the via hole.

According to another aspect of the inventive concept, there is provided a method of manufacturing a semiconductor device including a first structure including a first insulating layer and a first conductive wiring arranged on the first insulating layer, and a second structure including a second insulating layer and a second conductive wiring arranged on the second insulating layer, the method including forming, above the first structure in a first direction, a second-1 insulating layer that forms a lower portion of the second insulating layer, forming a via hole penetrating the second-1 insulating layer in the first direction, forming a barrier layer arranged at a lower side of an internal space of the via hole, etching a portion of the barrier layer arranged at an upper side within the internal space of the via hole, and forming a via plug electrically connected to the first conductive wiring by depositing a conductive material in a remaining space in the internal space of the via hole, excluding the barrier layer.

According to an embodiment, the forming of the via plug may be performed until the internal space of the via hole is filled with the conductive material by using an area selective deposition (ASD) method.

According to an embodiment, the method may further include forming an adhesive layer on a portion of a top surface of the second-1 insulating layer, on which the via plug is not formed, depositing a conductive material above the adhesive layer and the via plug, and forming a conductive pattern electrically connected to the via plug by etching the conductive material.

According to an embodiment, the forming of the adhesive layer may include depositing a self-assembled monolayer (SAM) on a top surface of the via plug, which is exposed to outside of the second-1 insulating layer, depositing an adhesive material on the top surface of the second-1 insulating layer, and removing the SAM via a plasma treatment.

According to an embodiment, the etching of the portion of the barrier layer may include forming a masking layer by depositing a masking material above the barrier layer, removing a portion of the masking layer such that the portion of the barrier layer, which is arranged at the upper side within the internal space of the via hole, is exposed to outside, removing the portion of the barrier layer, which is exposed outside the remaining masking layer, and removing the remaining masking layer.

According to an embodiment, the etching of the portion of the barrier layer may include depositing, above the barrier layer, a conductive material for forming at least a portion of the via plug, and performing a metal etch back process until the portion of the barrier layer, which is arranged at the upper side within the internal space of the via hole, is removed.

According to an embodiment, the forming of the via plug may be performed after performing the metal etch back process, and may include depositing a conductive material in the internal space of the via hole and above the second-1 insulating layer, and polishing the deposited conductive material to expose the second-1 insulating layer to outside.

According to still another aspect of the inventive concept, there is provided a semiconductor device including a first structure including a first insulating layer and a first conductive wiring arranged on the first insulating layer, a second-1 insulating layer arranged above the first structure in a first direction, a via plug penetrating the second-1 insulating layer in the first direction to be electrically connected to the first conductive wiring, and a barrier layer disposed between the via plug and the first conductive wiring and including a metal material having a higher thermal resistance than a metal material of the via plug.

### BRIEF DESCRIPTION OF THE DRAWINGS

Embodiments will be more clearly understood from the following detailed description taken in conjunction with the accompanying drawings in which:

FIG. 1 is a cross-sectional view showing a portion of a semiconductor device according to an embodiment;

FIG. 2 is an enlarged view of a portion A of FIG. 1;

FIG. 3 is a bottom perspective view showing a via plug and a barrier layer, according to an embodiment;

FIG. 4 is a cross-sectional view showing a portion of a semiconductor device according to an embodiment;

FIG. 5 is a cross-sectional view showing a portion of a semiconductor device according to an embodiment;

FIG. 6 is a flowchart showing a method of manufacturing a display apparatus, according to an embodiment;

FIG. 7 is a flowchart showing an operation of etching an upper portion of a barrier layer, according to an embodiment;

FIG. 8 is a flowchart showing an operation of forming an adhesive layer, according to an embodiment;

FIGS. 9A to 9J are diagrams showing a method of manufacturing a semiconductor device, according to an embodiment;

FIG. 10 is a flowchart showing a process of etching an upper portion of a barrier layer, according to an embodiment; and

FIGS. 11A and 11B are diagrams showing processes of etching an upper portion of a barrier layer, according to an embodiment.

### DETAILED DESCRIPTION OF THE EMBODIMENTS

Hereinafter, embodiments will be described in detail with reference to the accompanying drawings. However, various changes may be made to the embodiments, and thus, the scope of a right of the patent application is not limited by these embodiments. It is to be understood that all changes, equivalents, or substitutes for the embodiments are included in the scope of a right.

The terms used in the embodiments are merely used to describe the embodiments and are not intended to limit the embodiments. The expression of singularity includes the expression of plurality unless clearly specified otherwise in context. In the present specification, it is to be understood that the terms such as “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Herein, each of the expressions “A or B”, “at least one of A and B”, “at least one of A or B”, “A, B, or C”, “at least one of A, B, and C”, and “at least one of A, B, or C” may indicate any one of items listed in each of the expressions or any possible combination thereof.

Unless otherwise defined, all terms used herein, including technical or scientific terms, have the same meaning as those generally understood by a person skilled in the art in the technical field to which the embodiments belong. The terms defined in generally used dictionaries should be interpreted as having a meaning consistent with the meaning in the context of the related art, and unless explicitly defined in the present application, should not be interpreted in an ideal or excessively formal sense.

In addition, in the descriptions of the embodiments with reference to the accompanying drawings, like reference numerals may denote like components in different drawings, and redundant descriptions thereof will be omitted. In the descriptions of the embodiments, certain detailed explanations of the related art are omitted when it is deemed that they may unnecessarily obscure the essence of the embodiments.

In addition, the terms “first”, “second”, “A”, “B”, “(a)”, “(b)”, etc. may be used to describe components. These terms are only for distinguishing one component from another component, and the nature, sequence, or order of the components is not limited by these terms. When a component is said to be “connected”, “combined”, or “accessible” to another component, the component may be directly connected or accessible to the other component, but it is to be understood that another component may be “connected”, “combined”, or “accessed” between the components.

A component included in one embodiment and a component included in another embodiment, both of which include a common function, will be described using the same name. Unless stated otherwise, the description provided for one embodiment may be applied to another embodiment, and redundant detailed descriptions will be omitted.

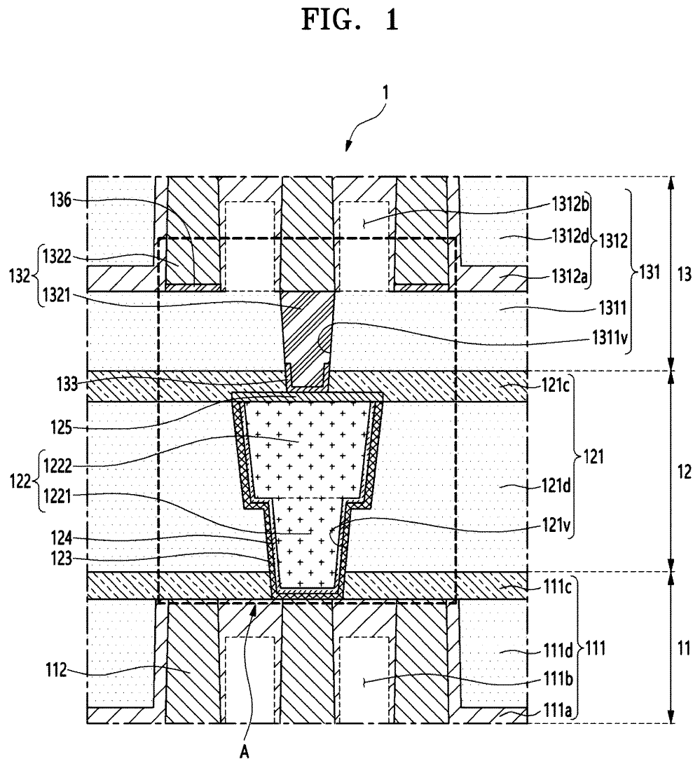

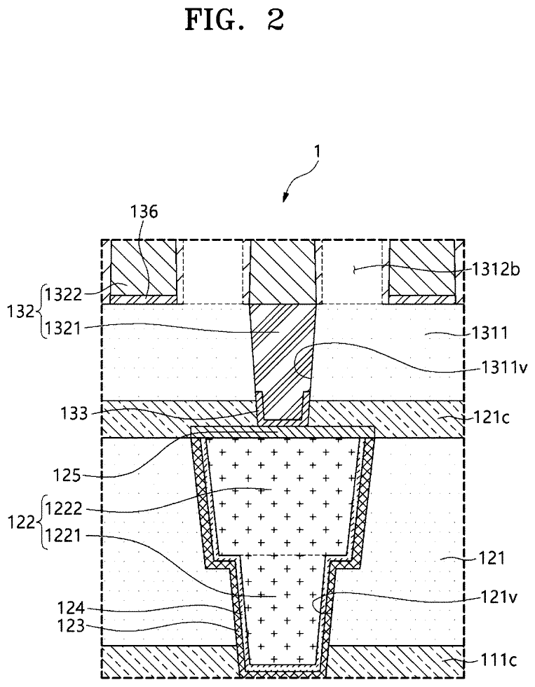

FIG. 1 is a cross-sectional view showing a portion of a semiconductor device according to an embodiment, and FIG. 2 is an enlarged view of a portion A of FIG. 1.

Referring to FIGS. 1 and 2, a semiconductor device 1 may include a lower structure 11, a first structure 12, and a second structure 13. The semiconductor device 1 may further include an additional structure arranged under and/above the lower structure 11, the first structure 12, and the second structure 13 in a first direction. Here, the first direction may refer to a vertical direction, but not limited thereto, which may be a direction parallel to a stacking direction of the lower structure 11, the first structure 12, and the second structure 13. The semiconductor device 1 may include, for example, a wafer substrate, a gate insulating layer formed above the wafer substrate via a front end of line (FEOL) process, an active layer including a gate electrode and/or source/drain regions, and a metal layer formed above the active layer via a back end of line (BEOL) process and including a metal wiring and a via plug. It may be understood that FIGS. 1 and 2 show a portion of the metal layer of the semiconductor device 1.

The lower structure 11 may include a lower insulating layer 111 and a lower conductive wiring 112 arranged on the lower insulating layer 111.

The lower insulating layer 111 may insulate the lower conductive wiring 112 from the first structure 12 or from another lower conductive wiring 112. The lower insulating layer 111 may include a lower interlayer insulating layer 111d, a protective layer 111a, an air gap 111b, and an etch stop layer 111c. Unless otherwise stated, the following description of the lower insulating layer 111 may also be applied to first and second insulating layers 121 and 131 respectively arranged in the first and second structures 12 and 13.

The lower interlayer insulating layer 111d may include a silicon-based insulating material. For example, the silicon-based insulating material may include silicon oxide (SiO), silicon oxycarbide (SiOC), silicon oxynitride (SiON), silicon oxycarbonitride (SiOCN), or silicon carbonitride (SiCN).

The protective layer 111a may support the lower conductive wiring 112 by surrounding the lower conductive wiring 112, thereby reducing damage to the lower conductive wiring 112. For example, the protective layer 111a includes a material that has a greater hardness than a material of the etch stop layer 111c or the lower interlayer insulating layer 111d of the lower insulating layer 111, and thus, even when the lower conductive wiring 112 includes a metal (for example, ruthenium (Ru)) that is vulnerable to heat, a problem of breakage due to heat may be reduced. For example, the protective layer 111a may include at least one of silicon carbonitride (SiCN) or silicon carbonitride (SiOCN). Unless otherwise stated, the description of the protective layer 111a may be applied to a protective layer 1312a arranged in the second structure 13.

The air gap 111b is formed within the lower insulating layer 111, and may be formed to surround a portion or all of a side surface of the lower conductive wiring 112. The air gap 111b may improve the performance of the overall semiconductor device 1 by reducing parasitic capacitance between a plurality of lower conductive wirings 112 that are adjacent to each other. For example, the air gap 111b may be formed within the protective layer 111a arranged between a pair of adjacent lower conductive wirings 112. Unless otherwise stated, the description of the air gap 111b may be applied to an air gap 1312b arranged in the second structure 13.

The etch stop layer 111c may reduce etching of the lower structure 11 during a process of etching a first interlayer insulating layer 121d of the first structure 12. The etch stop layer 111c may form a top surface of the lower structure 11 to cover a top surface of the lower conductive wiring 112. In addition, a portion of the etch stop layer 111c may be opened toward a via plug 1221 of the first structure 12 to receive/transmit a signal or power from/to the first structure 12. The etch stop layer 111c may include, for example, at least one of silicon carbide (SiC), silicon nitride (SiN), silicon carbonitride (SiCN), silicon boronitride (SiBN), silicon carbonate (SiCO), silicon nitride (SiON), silicon oxide (SiO), or silicon carbonitride (SiOCN). Unless otherwise stated, the description of the etch stop layer 111c may be applied to an etch stop layer 121c arranged in the first and second structures 12 and 13.

The lower conductive wiring 112 may include a conductive pattern that transmits a signal or power within the lower structure 11, and a via plug (not shown) that transmits a signal or power to another adjacent structure (for example, the active layer). For example, the lower conductive wiring 112 may include at least one of copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru).

For example, the lower conductive wiring 112 may include ruthenium (Ru) or molybdenum (Mo). Ruthenium (Ru) or molybdenum (Mo) is a material with a higher bulk resistivity than copper (Cu), but when the critical dimension (CD) of the lower conductive wiring 112 is reduced to several nanometers, for example, 20 nm or less or 10 nm or less, ruthenium (Ru) or molybdenum (Mo) may have less resistance than copper (Cu). The resistance of a structure with such a fine CD may be evaluated by using a resistivity scaling factor. In this regard, the “resistivity scaling factor” may be understood as a value (unit: 10\hat{ }(−16) Ωm\hat{ }2) obtained by multiplying the mean free path of an electron by the resistivity in a metal structure to be evaluated. The resistivity scaling factor for each material is measured at 8.2 for tungsten (W), 6.7 for copper (Cu), and 7.3 for cobalt (Co) based on the unit of 10\hat{ }(−16) Ωm\hat{ }2, whereas ruthenium (Ru) is measured at 5.1 and molybdenum (Mo) is measured at 6.0, which is lower than that of copper (Cu). Therefore, when the lower conductive wiring 112 includes ruthenium (Ru) or molybdenum (Mo), it is possible to reduce the CD of the lower conductive wiring 112 and a level at which resistance is increased. Unless otherwise stated, the description of the lower conductive wiring 112 may be applied to a second conductive wiring 132 arranged in the second structure 13.

The first structure 12 may be formed above the lower structure 11 and/or under the second structure 13 in the first direction (e.g., a vertical direction). For example, the first structure 12 may transmit power within the first structure 12 and/or to the lower structure 11 and the second structure 13. The first structure 12 may include a first insulating layer 121, a first conductive wiring 122, a barrier layer 123, a liner 124, and a capping layer 125.

The first insulating layer 121 may insulate the first conductive wiring 122 from the lower structure 11 and the second structure 13 or from another first conductive wiring 122. The first insulating layer 121 may include the first interlayer insulating layer 121d, a via hole 121v, and the etch stop layer 121c.

The first interlayer insulating layer 121d may include a silicon-based insulating material. For example, the silicon-based insulating material may include silicon oxide (SiO), silicon oxycarbide (SiOC), silicon oxynitride (SiON), silicon oxycarbonitride (SiOCN), or silicon carbonitride (SiCN).

The via hole 121v may be formed to penetrate at least a portion (for example, the etch stop layer 111c) of the lower insulating layer 111 in the first direction (e.g., a vertical direction). The barrier layer 123, the liner 124, and the first conductive wiring 122 may be deposited in the via hole 121v. The via hole 121v may function as a path through which the first conductive wiring 122 is electrically connected to the lower conductive wiring 112.

The etch stop layer 121c may reduce etching of the first structure 12 during a process of etching a second insulating layer 131 of the second structure 13. The etch stop layer 121c may form a top surface of the first structure 12 to cover a top surface of the first conductive wiring 122. In addition, a portion of the etch stop layer 121c may be opened toward a via plug 1321 of the second structure 13 to transmit a signal or power to the second structure 13.

The first conductive wiring 122 may be arranged on the first insulating layer 121. For example, the first conductive wiring 122 may transmit power or a signal within the first structure 12 and/or to the lower structure 11 and the second structure 13. For example, the first conductive wiring 122 may include at least one of copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru).

For example, when the first conductive wiring 122 transmits power to the etch stop layer 121c, the CD of the first conductive wiring 122 formed within the first structure 12 may be greater than the CD of each of the lower conductive wiring 112 and the second conductive wiring 132 respectively formed in the lower structure 11 and the second structure 13. For example, the CD of the first conductive wiring 122 may be greater than the CD of a signal transmission wiring among the lower conductive wiring 112 and the second conductive wiring 132 respectively formed in the lower structure 11 and the second structure 13. According to this structure, the resistance of the first conductive wiring 122 may be made relatively low, and thus, losses that may occur during power transmission may be reduced. For example, the first conductive wiring 122 may include a metal (for example, copper (Cu)) with a low bulk resistivity than a metal (for example, ruthenium (Ru) or molybdenum (Mo)) included in the lower conductive wiring 112 and/or the second conductive wiring 132 respectively arranged in the lower structure 11 and the second structure 13. The first conductive wiring 122 may include a via plug 1221 and a conductive pattern 1222.

The via plug 1221 may electrically connect the lower conductive wiring 112 to the conductive pattern 1222 by penetrating at least a portion of the first interlayer insulating layer 121d and the etch stop layer 111c. For example, the via plug 1221 may transmit power to the lower conductive wiring 112 arranged in the lower structure 11.

The conductive pattern 1222 may be electrically connected to the via plug 1221. A bottom surface of the conductive pattern 1222 may be in vertical contact with a top surface of the via plug 1221. For example, the conductive pattern 1222 may transmit power within the first insulating layer 121. For example, the conductive pattern 1222 may include a pad that transmits power to the via plug 1221 arranged in the first structure 12. For example, the conductive pattern 1222 may be formed simultaneously with the via plug 1221 by using a dual damascene process.

The barrier layer 123 may be arranged on an inner surface of the via hole 121v to cover a side surface and a bottom surface of the first conductive wiring 122. The barrier layer 123 may include a material that is capable of preventing a material (for example, copper (Cu)) included in the first conductive wiring 122 from spreading into the first insulating layer 121. For example, the barrier layer 123 may include at least one of a metal material, such as tantalum (Ta) or titanium (Ti), having higher thermal stability than other materials, or a metal nitride, such as tantalum nitride (TaN) or titanium nitride (TiN).

The liner 124 may be arranged on an inner surface of the barrier layer 123 to cover the side surface and the bottom surface of the first conductive wiring 122. The liner 124 improves adhesion between the barrier layer 123 and the material included in the first conductive wiring 122, and thus may help ensure that the material (for example, copper (Cu)) included in the first conductive wiring 122 fills a bottom surface of the via hole 121v without any air gap during a reflow process. For example, the liner 124 may include cobalt (Co).

The capping layer 125 may be formed at an upper side of the first structure 12 to cover a top surface of the conductive pattern 1222. The capping layer 125 may reduce electromigration of a material (for example, copper (Cu)) included in the conductive pattern 1222 to another adjacent structure and prevent oxidation of a surface of the conductive pattern 1222, thereby improving durability of the conductive pattern 1222. For example, the capping layer 125 may include cobalt (Co). For example, the capping layer 125 may be formed by using an electroless plating method. According to this method, the capping layer 125 may be formed to cover the entire top surface of the conductive pattern 1222 but not a top surface of the first insulating layer 121.

The second structure 13 may be formed above the first structure 12. The second structure 13 may include the second insulating layer 131, the second conductive wiring 132, a barrier layer 133, and an adhesive layer 136. The second insulating layer 131 may include a second-1 insulating layer 1311 and a second-2 insulating layer 1312.

The second-1 insulating layer 1311 may be arranged above the first structure 12. The second-1 insulating layer 1311 may include a silicon-based insulating material. For example, the silicon-based insulating material may include silicon oxide (SiO), silicon oxycarbide (SiOC), silicon oxynitride (SiON), silicon oxycarbonitride (SiOCN), or silicon carbonitride (SiCN).

The second-1 insulating layer 1311 may include a via hole 1311v formed to penetrate the second-1 insulating layer 1311 in the vertical direction. The via hole 1311v may be formed to penetrate at least a portion (for example, the etch stop layer 121c) of the first insulating layer 121 in the vertical direction. The barrier layer 133 and the second conductive wiring 132 may be deposited in the via hole 1311v. The via hole 1311v may function as a path through which the second conductive wiring 132 is electrically connected to the first conductive wiring 122. A portion of the barrier layer 133 may be embedded in the etch stop layer 121c, and another portion of the barrier layer 133 may protrude from a top surface of the etch stop layer 121c to be in direct contact with the second-1 insulating layer 1311.

For example, the CD of the via hole 1311v may be 20 nm or less, and the aspect ratio (AR) of the via hole 1311v may be 2 or less. In this regard, the “aspect ratio” refers to the height of the via hole 1311v relative to the diameter of the end of the via hole 1311v facing the first insulating layer 121, and when the AR increases, the via hole 1311v may have an elongated shape. According to this shape, the effect of an increase in total resistance due to the barrier layer 133 having a relatively greater resistance value than the second conductive wiring 132 may increase. As described below, by forming the barrier layer 133 only at a lower side of the via hole 1311v, the effect of this increase in resistance may be effectively reduced.

For example, the length (i.e., a value that is twice the thickness of the barrier layer 133) of a side wall of the barrier layer 133 within the via hole 1311v may be 5% to 10% of the cross-sectional diameter of the via hole 1311v. By setting the length to 5% or more, the possibility of a material, which is included in a conductive structure (for example, the first conductive wiring 122, the barrier layer 123, the liner 124, and the capping layer 125) of the first structure 12, spreading into the second conductive wiring 132, may be reduced. By setting the length to 10% or less, the resistance of the entire conductive structure within the via hole 1311v, occurring as a result of the barrier layer 133, may be reduced.

The second-2 insulating layer 1312 may be arranged above the second-1 insulating layer 1311 and the via plug 1321. The second-2 insulating layer 1312 may include an interlayer insulating layer 1312d, the protective layer 1312a, and the air gap 1312b.

The interlayer insulating layer 1312d may include, for example, a silicon-based insulating material. For example, the silicon-based insulating material may include silicon oxide (SiO), silicon oxycarbide (SiOC), silicon oxynitride (SiON), silicon oxycarbonitride (SiOCN), or silicon carbonitride (SiCN).

The protective layer 1312a may support a conductive pattern 1322 by surrounding the conductive pattern 1322 of the second structure 13, thereby reducing damage to the conductive pattern 1322.

The air gap 1312b is formed within the second insulating layer 131, and may be formed to surround a portion or all of a side surface of the conductive pattern 1322. For example, the air gap 1312b may be formed within the protective layer 1312a arranged between a pair of adjacent conductive patterns 1322.

The second conductive wiring 132 may be arranged on the second insulating layer 131. For example, the second conductive wiring 132 may transmit power or a signal within the second structure 13 and/or to the first structure 12. For example, the second conductive wiring 132 may include at least one of copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru).

For example, when the second conductive wiring 132 transmits a signal, the CD of the second conductive wiring 132 formed in the second structure 13 may be less than the CD of the first conductive wiring 122 formed in the first structure 12. For example, the CD of the second conductive wiring 132 may be less than the CD of a power transmission wiring among first conductive wirings 122 formed in the first structure 12. For example, the CD of the second conductive wiring 132 may be several nanometers, for example, 20 nm or less or 10 nm or less. For example, the second conductive wiring 132 may include a material that is different from the material included in the first conductive wiring 122. For example, the second conductive wiring 132 may include a material (for example, ruthenium (Ru) or molybdenum (Mo)) with a smaller resistivity scaling factor than the material (for example, copper (Cu)) included in the first conductive wiring 122. For example, the resistivity scaling factor of the material (for example, copper (Cu), tungsten (W), or cobalt (Co)) included in the first conductive wiring 122 may be greater than 6.5×10⁻¹⁶ Ωm², whereas the resistivity scaling factor of the material (for example, ruthenium (Ru) or molybdenum (Mo)) included in the second conductive wiring 132 may be less than 6.5×10⁻¹⁶ Ωm². According to this configuration, the second conductive wiring 132 may be formed to have a fine CD, and as a result, while miniaturization of the entire semiconductor device 1 is enhanced, a level at which resistance increases may be lowered, thereby improving the performance of the entire semiconductor device 1.

The second conductive wiring 132 may include the via plug 1321 and the conductive pattern 1322. The description of the material included in the second conductive wiring 132 may be applied to the via plug 1321 and the conductive pattern 1322. In addition, materials included in the via plug 1321 and the conductive pattern 1322 may be the same, but are not necessarily limited thereto. For example, the via plug 1321 may include ruthenium (Ru) and the conductive pattern 1322 may include molybdenum (Mo), or vice versa.

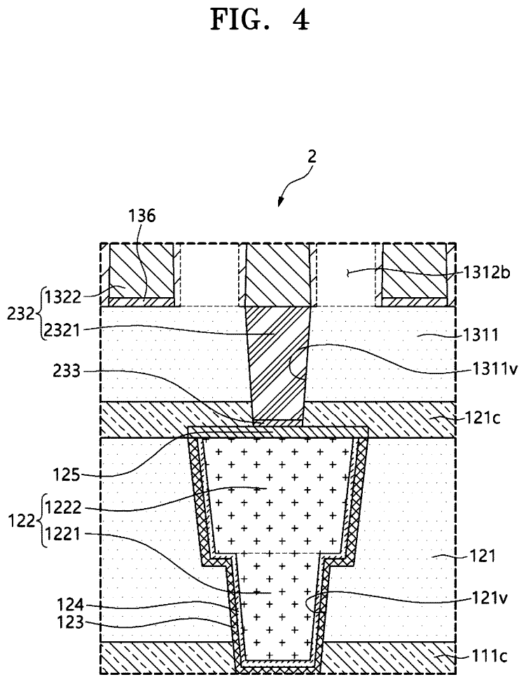

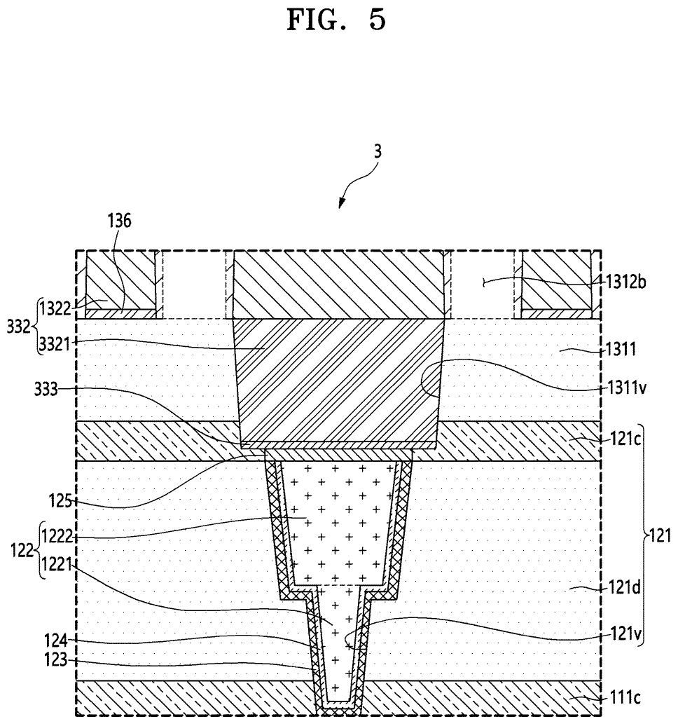

The via plug 1321 may be electrically connected to the first conductive wiring 122. The via plug 1321 may be arranged to fill the remaining space in an internal space of the via hole 1311v, excluding the barrier layer 133. For example, at least a portion of a side surface of the via plug 1321 may be in direct contact with the second-1 insulating layer 1311. The via plug 1321 may include a material (for example, ruthenium (Ru) or molybdenum (Mo)) with relatively less resistance than the barrier layer 133. According to this configuration, resistance to current flowing through the via plug 1321 and the barrier layer 133 may be reduced. In other words, there are no air gaps and/or dielectrics between the via plug 1321 and an inner wall of the via hole 1311v, and the entire internal space of the via hole 1311v is filled with a metal material, and thus, resistance is relatively reduced compared to a case where there are air gaps and/or dielectrics, and the performance of the entire semiconductor device 1 may be improved. For example, the via plug 1321 may include a material (for example, ruthenium (Ru) or molybdenum (Mo)) with a smaller possibility of diffusion into an insulating material than that of copper (Cu). According to this configuration, the need for the barrier layer 133 to be arranged between the via plug 1321 and the second-1 insulating layer 1311 is reduced, and thus, the barrier layer 133 may be formed not to cover the side surface of the via plug 1321 (see FIGS. 4 and 5) or may be formed to cover only a lower portion of the side surface of the via plug 1321.

The conductive pattern 1322 may be electrically connected to the via plug 1321 and may be arranged on the second-2 insulating layer 1312. A bottom surface of the conductive pattern 1322 may be in vertical contact with a top surface of the via plug 1321. For example, the conductive pattern 1322 may transmit a signal or power within the second insulating layer 131 and/or a conductive structure provided in another adjacent structure. For example, some of a plurality of conductive patterns 1322 may be electrically connected to the conductive pattern 1222 of the first structure 12 to transmit power to the conductive pattern 1222 of the first structure 12. For example, the CD of the conductive pattern 1322 may be less than the CD of the first conductive wiring 122. For example, the CD of the conductive pattern 1322 for transmitting a signal among the plurality of conductive patterns 1322 may be less than the CD of the first conductive wiring 122. For example, the conductive pattern 1322 may include a metal (for example, ruthenium (Ru) or molybdenum (Mo)) that is different from that of the first conductive wiring 122.

The barrier layer 133 may be arranged between the first conductive wiring 122 and the via plug 1321. For example, the barrier layer 133 may include at least one of tantalum (Ta), tantalum nitride (TaN), titanium (Ti), or titanium nitride (TiN), which has higher thermal stability than other materials. According to the barrier layer 133, even when the first conductive wiring 122 and the via plug 1321 include different materials from each other, a problem of diffusion between dissimilar metals may be reduced.

For example, when copper (Cu) is utilized as a wiring metal, a minimum width for copper growth is required. Due to this limitation in Cu fill margin, there is a limit to the CD of a wiring including copper. However, in order to transmit power, a wiring having a certain width or more is advantageous. Therefore, a conductive wiring (for example, the conductive pattern 1222 of the first structure 12) that transmits power may be formed to have a sufficiently large CD by using copper (Cu), which has a relatively low bulk resistivity. In addition, a conductive wiring (for example, the conductive pattern 1322 of the second structure 13) that transmits a signal may be formed to have a fine CD by using ruthenium (Ru) or molybdenum (Mo), which has a relatively low resistivity scaling factor. As such, a plurality of wirings that are adjacent to each other may include different materials from each other depending on their purposes. In this case, diffusion between dissimilar metals is likely to be a problem, but the barrier layer 133 may help reduce this problem.

In other words, the barrier layer 133 may help reduce diffusion of a material (for example, cobalt (Co)) included in a conductive structure (for example, the first conductive wiring 122, the barrier layer 123, the liner 124, and the capping layer 125) arranged in the first structure 12 into a material (for example, ruthenium (Ru)) included in a conductive structure (for example, the via plug 1321 and the conductive pattern 1322) arranged in the second structure 13.

For example, the first conductive wiring 122 may include copper (Cu), the liner 124 or the capping layer 125 of the first structure 12 may include cobalt (Co), and the via plug 1321 may include ruthenium (Ru). Cobalt (Co) has a tendency to diffuse into ruthenium (Ru), and thus, cobalt (Co) included in the liner 124 or the capping layer 125 diffuses into ruthenium (Ru) included in the via plug 1321, and as a result, an air gap may be formed in the first conductive wiring 122. The possibility of such air gap formation may be reduced by the barrier layer 133. In addition, the barrier layer 133 includes a material with higher resistance than the second conductive wiring 132, and thus, loss of a signal or power passing through the via hole 1311v may occur.

In order to reduce the above-described problem, the barrier layer 133 may be arranged only at the lower side of the via hole 1311v and may not be arranged at an upper side of the via hole 1311v. In other words, the barrier layer 133 may be formed to cover only a lower portion of the via plug 1321. The barrier layer 133 may include a bottom surface arranged at a bottom end of the via hole 1311v. According to this shape, the volume of the via plug 1321 including a relatively low-resistance conductive material (for example, ruthenium (Ru) or molybdenum (Mo)) within the internal space of the via hole 1311v is increased, and thus, resistance to current flowing through the via plug 1321 and the barrier layer 133 may be reduced. For example, the height of the barrier layer 133 may be less than or equal to half the height of the via hole 1311v, but is not necessarily limited thereto.

The adhesive layer 136 may be formed on a portion of a top surface of the second-1 insulating layer 1311, on which the via plug 1321 is not formed. For example, the adhesive layer 136 may include at least one of titanium nitride (TiN) or tantalum nitride (TaN). For example, the adhesive layer 136 may include a same material as the barrier layer 133. The adhesive layer 136 may improve a bonding force between the second-1 insulating layer 1311 and the conductive pattern 1322, thereby improving mechanical stability of the semiconductor device 1. Therefore, the conductive pattern 1322 may be formed even with a material (for example, ruthenium (Ru)) with low adhesion to an insulating material.

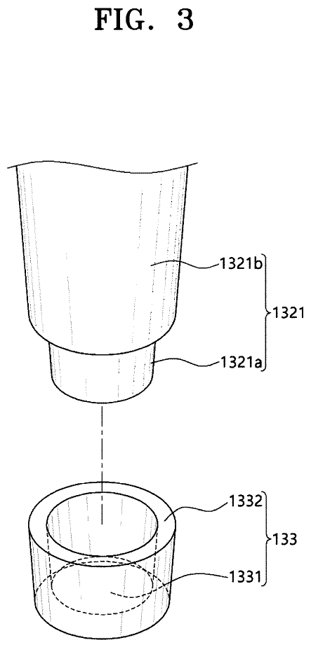

FIG. 3 is a bottom perspective view showing a via plug and a barrier layer, according to an embodiment.

Referring to FIGS. 2 and 3, the barrier layer 133 may include a bottom layer 1331 and a side wall 1332.

The side wall 1332 may extend upward from an edge of the bottom layer 1331 along the inner wall of the via hole 1311v. The side wall 1332 may be arranged between a lower side surface of the via plug 1321 and the second-1 insulating layer 1311. According to the side wall 1332, without excessively increasing the thickness of the bottom layer 1331, the possibility of diffusion of a material included in the capping layer 125 and/or the liner 124 into the second conductive wiring 132 may be reduced. For example, the height of the side wall 1332 may be less than or equal to half the total height of the via hole 1311v.

In one example, the “total height” of the via hole 1311v may mean the distance between the upper surface of the second-1 insulating layer 1311 and the bottom surface of the barrier layer 133 (or the via hole 1311v), and the “height” of the barrier layer 133 or the side wall 1332 may mean the distance between the upper surface of the side wall 1332 and the bottom surface of the barrier layer 133 (or the via hole 1311v). Such distances may be the minimum distance among distances between the two surfaces, measured at multiple points (e.g., 5) of one of the two surfaces in the first direction (e.g., a vertical direction), or may be the average distance of the measured distances at the multiple points. Such measured distances at the multiple points may be obtained from a microscopic image(s), e.g., a scanning microscope (SEM) image, of one or more cut surfaces of the semiconductor device 1 (e.g., the cross-sectional view in FIG. 1). Other methods and/or tools appreciated by one of ordinary skill in the art, even if not described in the present disclosure, may also be used. In addition, the measurement of a height is not limited these examples, and one of ordinary skill in the art may select the number of measurement points, the interval therebetween, and so forth, if necessary. For example, the number of measurement points may be 3, 5, or 10 per one distance, but is not limited thereto.

As shown in the drawings, the via plug 1321 may have a shape stepped inward from a lower outer surface of the via plug 1321, and the side wall 1332 may be accommodated in the stepped shape.

In other words, the via plug 1321 may include a first portion 1321a having an outer surface surrounded by the side wall 1332 of the barrier layer 133, and a second portion 1321b having an outer surface that is not surrounded by the side wall 1332 of the barrier layer 133. As shown in the drawings, the outer surface of the second portion 1321b may extend along the inner wall of the via hole 1311v and may form a continuous surface with an outer surface of the side wall 1332. In other words, an upper portion of the side wall 1332 is filled with a metal material with higher conductivity than an air gap or a dielectric, and thus, loss of a signal or power passing through the via hole 1311v may be reduced.

FIG. 4 is a cross-sectional view showing a portion of a semiconductor device according to an embodiment.

Referring to FIGS. 1 and 4, a semiconductor device 2 may include the lower structure 11, the first structure 12, and the second structure 13. The lower structure 11 may include the lower insulating layer 111 and the lower conductive wiring 112. The first structure 12 may include the first insulating layer 121, the first conductive wiring 122, the barrier layer 123, the liner 124, and the capping layer 125. The second structure 13 may include the second insulating layer 131, a second conductive wiring 232, a barrier layer 233, and the adhesive layer 136. Unless otherwise stated, the description of the semiconductor device 1 provided with reference to FIGS. 1 and 2 may be applied to the semiconductor device 2 shown in FIG. 4.

The second conductive wiring 232 may include a via plug 2321 and the conductive pattern 1322. For example, a bottom end of the via plug 2321 may have a flat shape.

The barrier layer 233 may have, for example, a flat plate shape covering a bottom surface of the via hole 1311v. In other words, the barrier layer 233 may cover the bottom surface of the via hole 1311v and may not include a side wall protruding upward. According to this shape, resistance may be reduced compared to a case where the barrier layer 233 includes a side wall.

FIG. 5 is a cross-sectional view showing a portion of a semiconductor device according to an embodiment.

Referring to FIGS. 1 and 5, a semiconductor device 3 may include the lower structure 11, the first structure 12, and the second structure 13. The lower structure 11 may include the lower insulating layer 111 and the lower conductive wiring 112. The first structure 12 may include the first insulating layer 121, the first conductive wiring 122, the barrier layer 123, the liner 124, and the capping layer 125. The second structure 13 may include the second insulating layer 131, a second conductive wiring 332, a barrier layer 333, and the adhesive layer 136. Unless otherwise stated, the description of the semiconductor device 1 provided with reference to FIGS. 1 to 4 may be applied to the semiconductor device 3 shown in FIG. 5.

The second conductive wiring 332 may include a via plug 3321 and a conductive pattern.

The diameter of the barrier layer 333 may be greater than the diameter of a portion of the first conductive wiring 122, which is exposed through the via hole 121v. For example, the barrier layer 333 may have a greater diameter than the diameter of the capping layer 125 or the via hole 121v of the first structure 12. According to this shape, the length of a path from a conductive structure (for example, the first conductive wiring 122, the barrier layer 123, the liner 124, and the capping layer 125) arranged in the first structure 12 to the via plug 3321, bypassing the barrier layer 333, may be increased. Therefore, as the possibility of diffusion between dissimilar metals decreases, a side wall may be removed from the barrier layer 333, or the thickness of a bottom layer of the barrier layer 333 may be reduced, thereby reducing the effect of an increase in resistance due to the barrier layer 333.

Although it is shown that the barrier layer 333 has a flat plate shape, the barrier layer 333 may include a side wall protruding upward from the bottom layer or an edge of the bottom layer, as described with reference to FIG. 3.

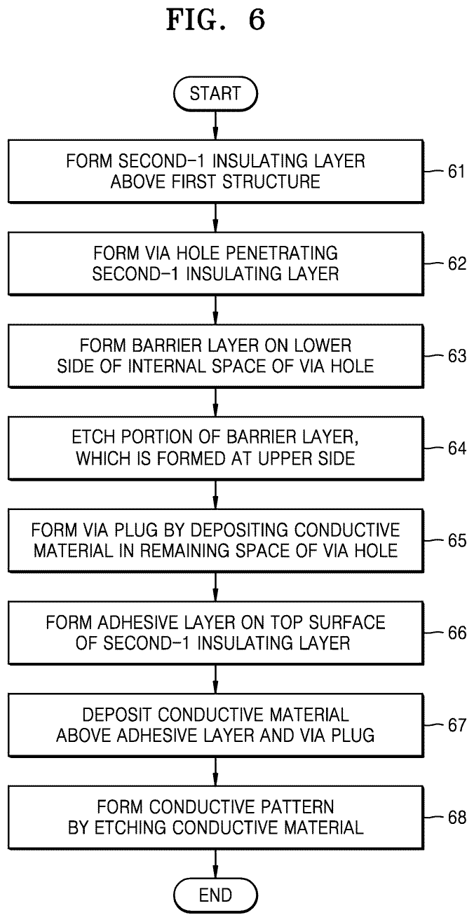

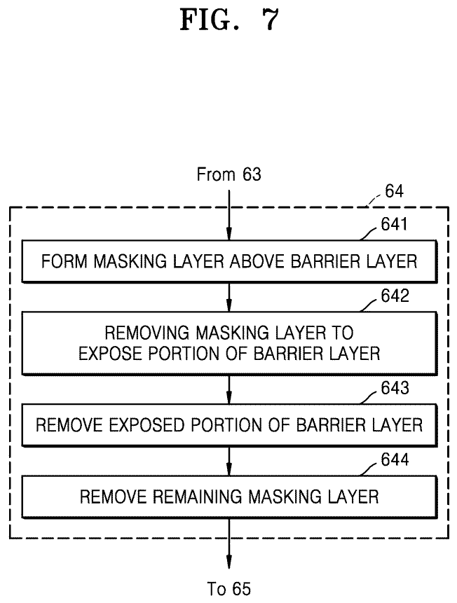

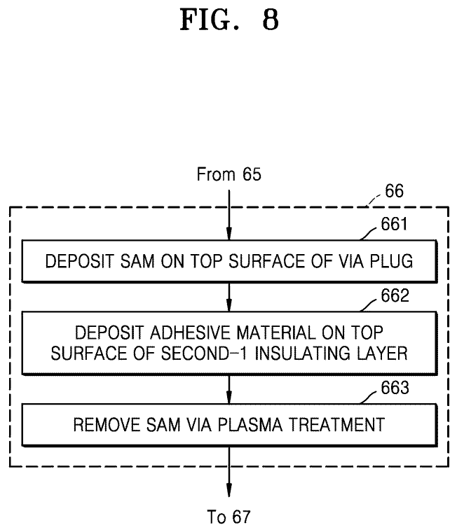

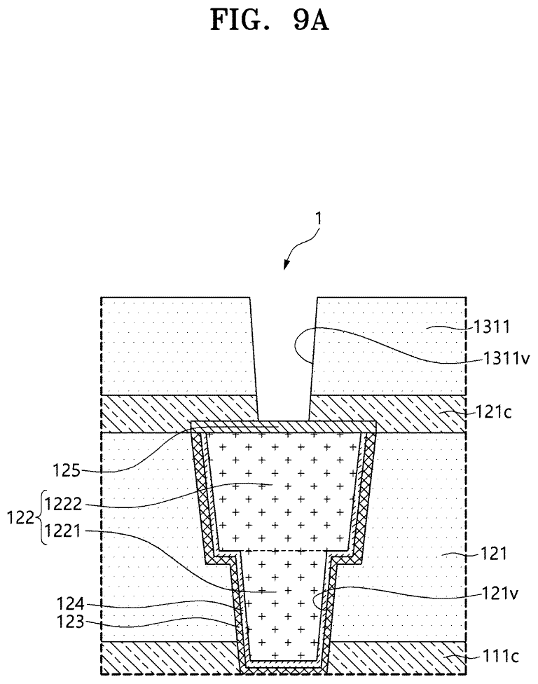

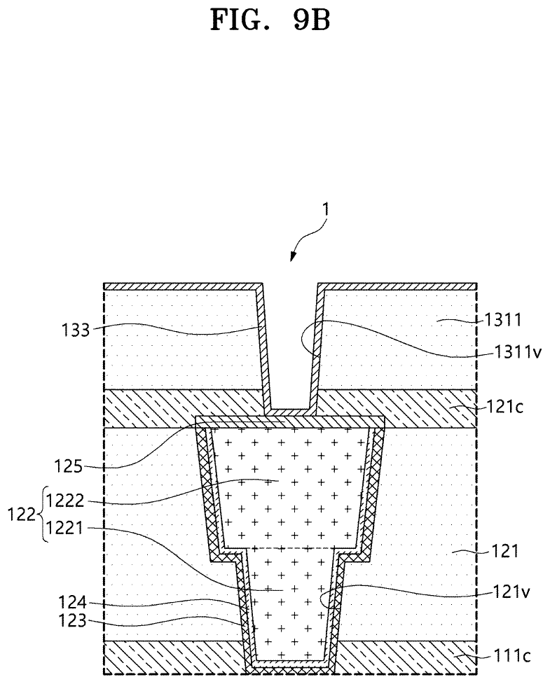

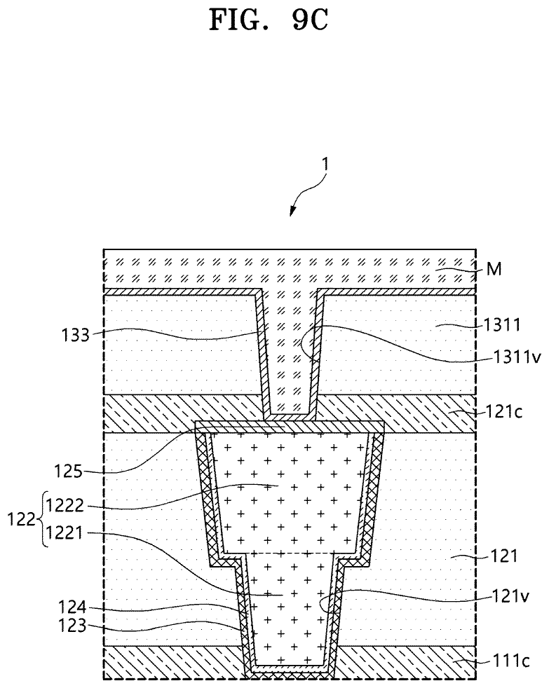

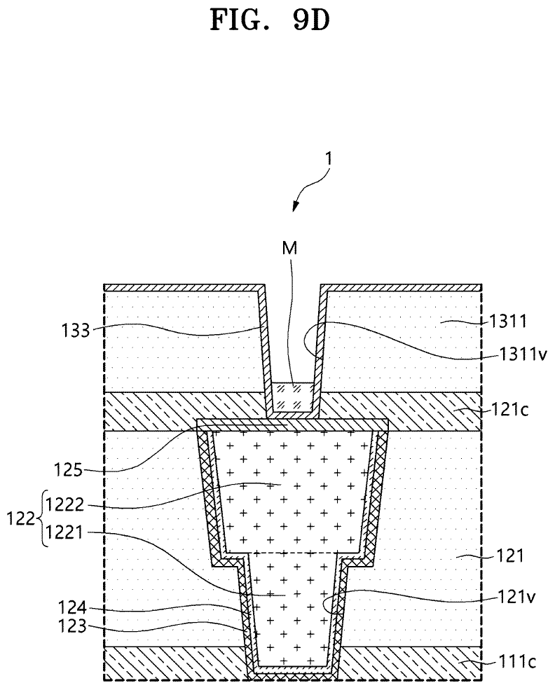

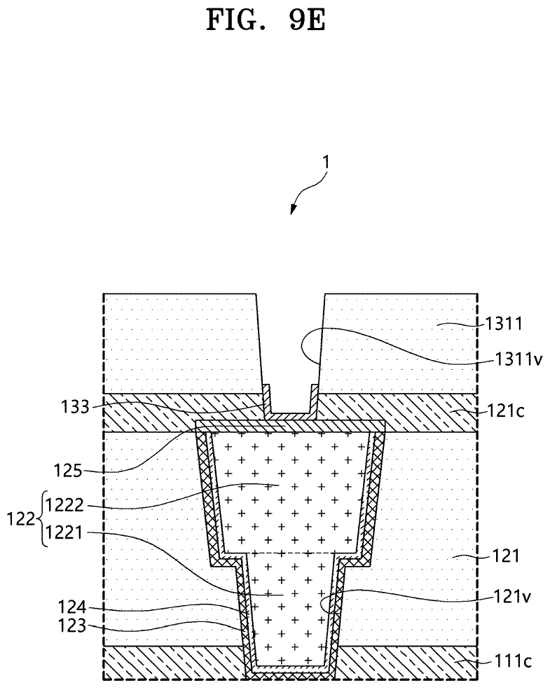

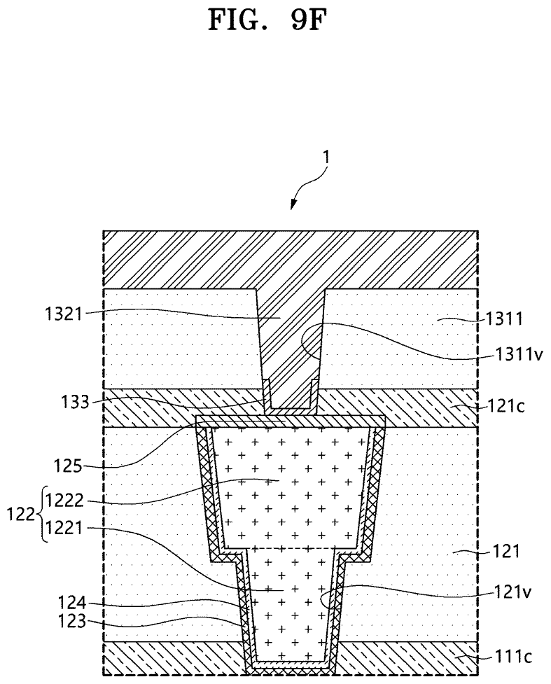

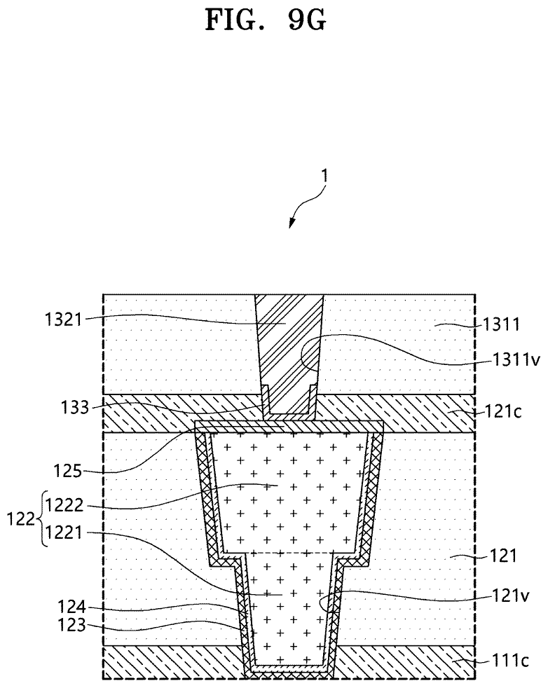

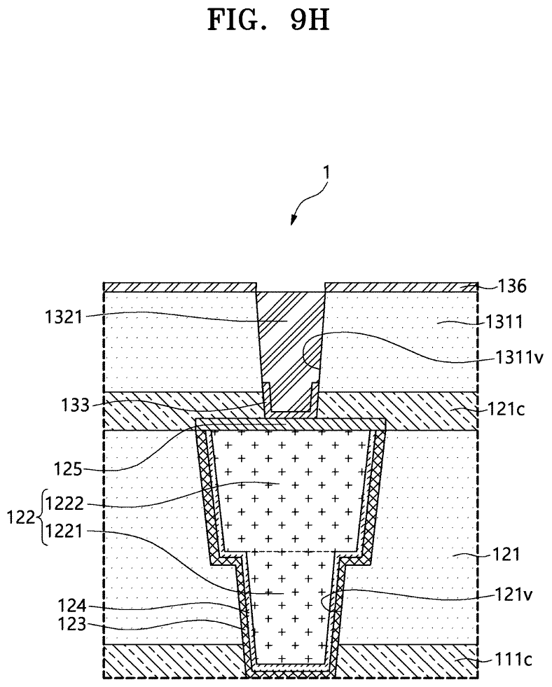

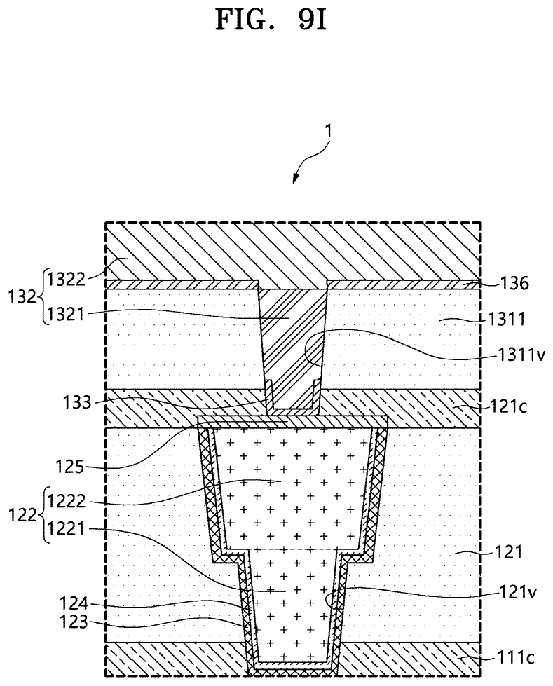

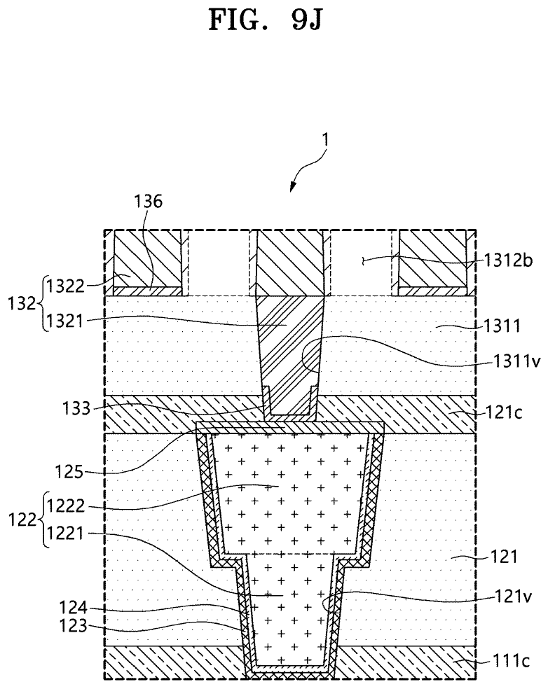

FIG. 6 is a flowchart showing a method of manufacturing a semiconductor device, according to an embodiment, FIG. 7 is a flowchart showing an operation of etching an upper portion of a barrier layer, according to an embodiment, and FIG. 8 is a flowchart showing an operation of forming an adhesive layer, according to an embodiment. FIGS. 9A to 9J are diagrams showing a method of manufacturing a semiconductor device, according to an embodiment.

A method of manufacturing the semiconductor device 1 including the first structure 12 including the first insulating layer 121 and the first conductive wiring 122 and the second structure 13 including the second insulating layer 131 and the second conductive wiring 132 is described with reference to FIGS. 6 to 9J. It may be understood that FIGS. 6 to 9J show an example of a method of manufacturing the semiconductor device 1 shown in FIG. 1.

Referring to FIGS. 6 to 9A, in operation 61, the second-1 insulating layer 1311 that forms a lower portion of the second insulating layer 131 may be formed above the first structure 12. In operation 62, the via hole 1311v that penetrates the second-1 insulating layer 1311 in the vertical direction may be formed.

Referring to FIGS. 6 and 9B, in operation 63, the barrier layer 133 arranged at a lower side of an internal space of the via hole 1311v may be formed. The barrier layer 133 may include, for example, at least one of tantalum nitride (TaN), titanium nitride (TiN), molybdenum (Mo), tungsten (W), titanium dioxide (TiO₂), titanium (Ti), titanium nitride (TiN), titanium carbide (TIC), tantalum nitride (TaN), tantalum carbide (TaC), tantalum boride (TaB), molybdenum tungsten (MoW), tungsten carbide (WC), tungsten nitride (WN), or cobalt tungsten (CoW). For example, the barrier layer 133 may be formed via a deposition process. The deposition process may include a physical vapor deposition (PVD), atomic layer deposition (ALD), chemical vapor deposition (CVD), or sputtering method. For example, operation 63 may be performed via a deposition process such as a CVD or ALD method. This method has excellent deposition efficiency for a narrow region, and thus, the barrier layer 133 may be uniformly formed up to the bottom surface of the via hole 1311v having a fine CD.

Referring to FIGS. 6 and 7, in operation 64, a portion of the barrier layer 133, which is arranged at an upper side within the internal space of the via hole 1311v, may be etched. For example, operation 64 may be performed by using a masking material as shown in FIGS. 9C to 9E. The masking material may include, for example, a spin-on hardmark (SOH) material.

Referring to FIGS. 7 and 9C, in operation 641, a masking layer M may be formed by depositing a masking material (for example, SOH) above the barrier layer 133. The masking layer M may protect the barrier layer 133 formed at the lower side of the via hole 1311v from being etched during an etching process described below. Operation 641 may be performed by using, for example, a spin coating, slot die coating, or dipping method.

Referring to FIGS. 7 and 9D, in operation 642, a portion of the masking layer M may be removed such that the portion of the barrier layer 133, which is arranged at the upper side within the internal space of the via hole 1311v, is exposed to the outside. For example, operation 642 may be performed via a plasma treatment (for example, plasma etching). According to operation 642, the masking layer M arranged on a top surface of the second-1 insulating layer 1311 may be removed. Operation 642 may be performed until the height of the masking layer M reaches a certain height (for example, a height that is substantially equal to half the height of the via hole 1311v) less than the height of the via hole 1311v.

As used herein, the expression “substantially equal” may refer to the same height, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

In operation 643, a portion of the barrier layer 133 may be removed. In this regard, the portion of the barrier layer 133 refers to a portion that is exposed outside the remaining masking layer M. For example, operation 643 may be performed via an etching process. The etching process may include wet etching and dry etching methods. The dry etching method may include a plasma etching method, a sputter etching method, or a reactive ion etching method.

In operation 644, by removing the remaining masking layer M, the barrier layer 133 may be formed to have a shape arranged only at the lower side of the via hole 1311v, as shown in FIG. 9E. For example, operation 644 may be formed via a plasma treatment, like operation 642.

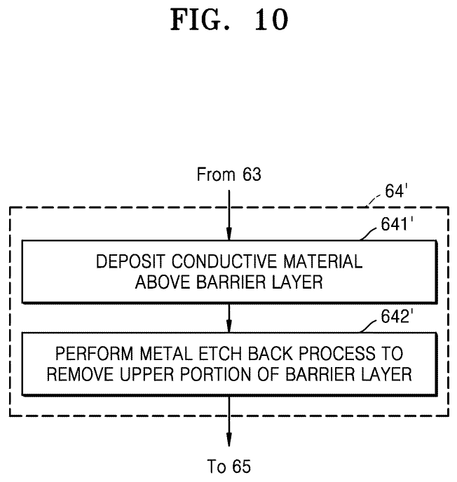

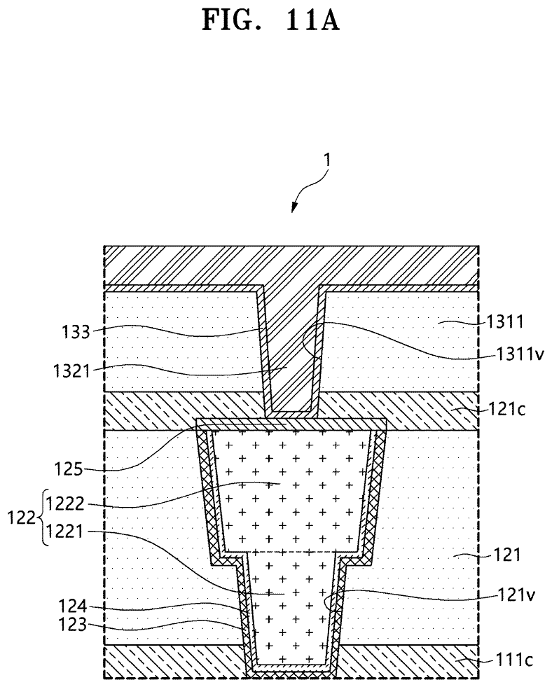

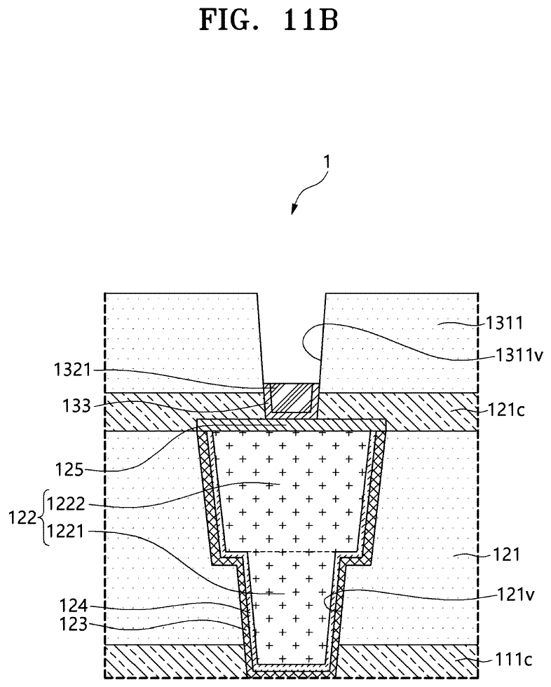

Hereinbefore, a case where operation 64 is performed by using a masking material is described as an example, but operation 64 may be performed in a different manner, which is described below with reference to FIGS. 10, 11A, and 11B.

Referring to FIG. 6, in operation 65, the via plug 1321 may be formed by depositing a conductive material (for example, ruthenium (Ru) or molybdenum (Mo)) in the remaining space in the internal space of the via hole 1311v, excluding the barrier layer 133.

For example, operation 65 may be performed via processes shown in FIGS. 9F and 9G. For example, as shown in FIG. 9F, the conductive material may be deposited higher than the height of the second-1 insulating layer 1311 such that the conductive material may sufficiently fill up to a top end of the entire via hole 1311v. For example, operation 65 may include a deposition process. For example, operation 65 may include a deposition process such as a PVD method. This method enables deposition of a target material in large quantities at a low cost and has an advantage in that the purity of a process result is high.

Afterwards, as shown in FIG. 9G, the via plug 1321 may be formed by polishing the deposited conductive material via a polishing process (for example, chemical mechanical polishing (CMP)). The polishing process may be performed so that the second-1 insulating layer 1311 is exposed.

As another example, in operation 65, the process corresponding to FIG. 9F may be omitted. In operation 65, the internal space of the via hole 1311v may be filled with the conductive material by using an arca selective deposition (ASD) method. According to this method, deposition of the conductive material in an external space of the via hole 1311v may be prevented, and thus, the polishing process may be omitted.

Referring to FIGS. 6 and 9H, in operation 66, the adhesive layer 136 may be formed on a portion of a top surface of the second-1 insulating layer 1311, on which the via plug 1321 is not formed. The adhesive layer 136 may include, for example, at least one of titanium (Ti), titanium dioxide (TiO₂), titanium carbide (TiC), tantalum (Ta), tantalum nitride (TaN), tantalum carbide (TaC), or tantalum boride (TaB).

Referring to FIG. 8, operation 66 may proceed by using, for example, a self-assembled monolayer (SAM). In operation 661, the SAM may be deposited on a top surface of the via plug 1321, which is exposed to the outside of the second-1 insulating layer 1311. In operation 662, an adhesive material may be deposited on the top surface of the second-1 insulating layer 1311. In operation 662, the adhesive material may be deposited on a top surface of the SAM arranged above the via plug 1321, but may be removed via operation 663. In operation 663, the SAM and the adhesive material deposited on the top surface of the SAM may be removed via a plasma treatment. Via this process, as shown in 9H, it is possible to prevent the adhesive layer 136 from being formed on the top surface of the via plug 1321. As another example, operation 66 may be performed via a photolithography process employing a photosensitive material and a mask.

Referring to FIGS. 6 and 9I, in operation 67, a conductive material (for example, ruthenium (Ru) or molybdenum (Mo)) may be deposited above the adhesive layer 136 and the via plug 1321. As shown in FIG. 9I, the conductive material may be directly deposited on the top surface of the via plug 1321, thereby reducing resistance between the via plug 1321 and the conductive pattern 1322. For example, operation 67 may be performed via a deposition process such as a PVD method.

Referring to FIGS. 6 and 9J, in operation 68, the conductive pattern 1322 electrically connected to the via plug 1321 may be formed by etching the conductive material deposited above the second-1 insulating layer 1311. For example, operation 68 may be performed by using a dry etching method. For example, operation 68 may be performed by using a reactive ion etching method or a plasma etching method, which allows for selective etching.

FIG. 10 is a flowchart showing a process of etching an upper portion of a barrier layer, according to an embodiment, and FIGS. 11A and 11B are diagrams showing processes of etching an upper portion of a barrier layer, according to an embodiment.

Referring to FIGS. 6 and 10, in operation 64′, a portion of the barrier layer 133, which is arranged at an upper side within the internal space of the via hole 1311v, may be etched. For example, operation 64′ may be performed by using a metal etch back process instead of using a masking material, as shown in FIGS. 11A and 11B. FIGS. 11A and 11B may be understood as processes that replace the processes shown in FIGS. 9C to 9E among the processes shown in FIGS. 9A to 9J.

Referring to FIGS. 10 and 11A, in operation 641′, a conductive material (for example, ruthenium (Ru) or molybdenum (Mo)) for forming at least a portion of the via plug 1321 may be deposited above the barrier layer 133. For example, as shown in FIG. 11A, the conductive material may be deposited higher than the height of the second-1 insulating layer 1311. According to this method, the conductive material may sufficiently fill up to a top end of the entire via hole 1311v. For example, operation 641′ may be performed via a deposition process such as a PVD method.

Referring to FIGS. 10 and 11B, in operation 642′, the metal etch back process may be performed on the barrier layer 133 and the conductive material deposited above the barrier layer 133. The metal etch back process may be performed until the portion of the barrier layer 133, which is arranged at the upper side within the internal space of the via hole 1311v, is removed. Operation 642′ may be performed by using, for example, a reactive ion etching method which allows for selective etching. After operation 642′ is performed, the via plug 1321 and the conductive pattern 1322 may be formed via operation 65 and operation 68.

Unlike the above, in the state shown in FIG. 11B, the via plug 1321 and the conductive pattern 1322 may be formed by depositing the conductive material in the remaining space of the via hole 1311v and above the second-1 insulating layer 1311 via a single deposition process, and by etching the conductive material deposited above the second-1 insulating layer 1311. In other words, after operation 642′ and operation 65 are performed, operation 68 may be performed without operation 66 and operation 67. According to this method, the cost and time required for manufacturing the semiconductor device 1 may be reduced.

As described above, although the embodiments have been described by the limited drawings, various technical modifications and variations may be applied based on the above description by those of ordinary skill in the art. For example, even if the described technologies are performed in an order different from the described method, and/or components such as the described system, structure, device, circuit, etc. are coupled or combined in a form different from the described method, or are replaced or substituted by other components or equivalents, an appropriate result may be achieved.

Therefore, other implementations, other embodiments, and those equivalent to the claims also fall within the scope of the claims to be described below.

While the inventive concept has been particularly shown and described with reference to embodiments thereof, it will be understood that various changes in form and details may be made therein without departing from the spirit and scope of the following claims.

What is claimed is:

1. A semiconductor device comprising:
a first structure including a first insulating layer and a first conductive wiring arranged on the first insulating layer;
a second-1 insulating layer arranged above the first structure in a first direction;
a via hole penetrating the second-1 insulating layer in the first direction;
a barrier layer arranged at a lower side of the via hole; and
a via plug electrically connected to the first conductive wiring and arranged to fill a remaining space in an internal space of the via hole, excluding the barrier layer.

2. The semiconductor device of claim 1, wherein at least a portion of a side surface of the via plug is in direct contact with the second-1 insulating layer.

3. The semiconductor device of claim 1, wherein the barrier layer comprises a bottom layer covering a lower portion of the via plug, and
a height of the barrier layer is less than or equal to half a height of the via hole.

4. The semiconductor device of claim 3, wherein the barrier layer further comprises a side wall extending upward from an edge of the bottom layer along an inner wall of the via hole and arranged between a lower side surface of the via plug and the second-1 insulating layer.

5. The semiconductor device of claim 4, wherein the via plug has a shape stepped inward from an outer surface of the via plug, and
the side wall of the barrier layer is accommodated in the stepped shape of the via plug.

6. The semiconductor device of claim 5, wherein the via plug comprises:
a first portion having an outer surface surrounded by the side wall of the barrier layer; and
a second portion having an outer surface that is not surrounded by the side wall of the barrier layer, and
the outer surface of the second portion extends along the inner wall of the via hole and forms a continuous surface with an outer surface of the side wall of the barrier layer.

7. The semiconductor device of claim 1, wherein the first conductive wiring and the via plug are formed of different metals.

8. The semiconductor device of claim 7, wherein the resistivity scaling factor of the material forming the first conductive wiring is greater than 6.5×10⁻¹⁶ Ωm², and the resistivity scaling factor of the material forming the via plug is less than 6.5×10⁻¹⁶ Ωm².

9. The semiconductor device of claim 7, wherein the first conductive wiring includes Cu, and the via plug includes Ru.

10. The semiconductor device of claim 1, further comprises:
a second-2 insulating layer disposed on the upper side of the second-1 insulating layer and the via plug, and
a conductive pattern electrically connected to the via plug and disposed on the second-2 insulating layer, wherein the conductive pattern is formed of a different metal from the first conductive wiring.

11. The semiconductor device of claim 10, wherein the critical dimension (CD) of the conductive pattern is smaller than the critical dimension (CD) of the first conductive wiring.

12. The semiconductor device of claim 1, wherein the critical dimension of the via hole further is 20 nm or less, and the aspect ratio (AR) of the via hole is 2 or less.

13. The semiconductor device of claim 1, wherein the diameter of the barrier layer is larger than the diameter of the portion of the first conductive wiring exposed through the via hole.

14. A method of manufacturing a semiconductor device comprising a first structure including a first insulating layer and a first conductive wiring arranged on the first insulating layer; and a second structure including a second insulating layer and a second conductive wiring arranged on the second insulating layer, the method comprising:
forming, above the first structure in a first direction, a second-1 insulating layer that forms a lower portion of the second insulating layer;
forming a via hole penetrating the second-1 insulating layer in the first direction;
forming a barrier layer arranged at a lower side of an internal space of the via hole;
etching a portion of the barrier layer arranged at an upper side within the internal space of the via hole; and
forming a via plug electrically connected to the first conductive wiring by depositing a conductive material in a remaining space in the internal space of the via hole, excluding the barrier layer.

15. The method of claim 14, wherein the step of forming the via plug is performed using an area selective deposition (ASD) method until the internal space of the via hole is filled with the conductive material.

16. The method of claim 14, further comprising:
forming an adhesive layer on a portion of a top surface of the second-1 insulating layer, on which the via plug is not formed;
depositing a conductive material above the adhesive layer and the via plug; and
forming a conductive pattern electrically connected to the via plug by etching the conductive material.

17. The method of claim 16, wherein the step of forming the adhesive layer includes:
depositing a self-assembled monolayer (SAM) on the upper surface of the via plug exposed to the outside of the second-1 insulating layer;
depositing am adhesive material on the upper surface of the second-1 insulating layer; and
removing the self-assembled monolayer through plasma treatment.

18. The method of claim 14, wherein the etching of the portion of the barrier layer comprises:
forming a masking layer by depositing a masking material above the barrier layer;
removing a portion of the masking layer such that the portion of the barrier layer, which is arranged at the upper side within the internal space of the via hole, is exposed to outside;
removing the portion of the barrier layer, which is exposed outside the remaining masking layer; and
removing the remaining masking layer.

19. The method of claim 14, wherein the etching of the portion of the barrier layer comprises:
depositing, above the barrier layer, a conductive material for forming at least a portion of the via plug; and
performing a metal etch back process until the portion of the barrier layer, which is arranged at the upper side within the internal space of the via hole, is removed.

20. The method of claim 19, wherein the step of forming the via plug is performed after the step of preforming the metal etch back process,
and further comprising a step of depositing a conductive material on the internal space of the via hole and the upper side of the second-1 insulating layer; and polishing the deposited conductive material so that the second-1 insulating layer is exposed to outside.
